(19) United States
(12) Patent Application Publication
(10) Pub. No.: US 2010/0288190 A1
(43) Pub. Date: Nov. 18, 2010

(54) Growth Method of Non-Polarized-Plane InN

(75) Inventors: RONG ZHANG, Nanjing (CN); ZILI XIE, Nanjing (CN); BIN LIU, Nanjing (CN); XIANGQIAN XIU, Nanjing (CN); HONG ZHAO, Nanjing (CN); XUEMEI HUA, Nanjing (CN); PING HAN, Nanjing (CN); DEYI FU, Nanjing (CN); YI SHI, Nanjing (CN); YOUDOU ZHENG, Nanjing (CN)

Correspondence Address: GLOBAL IP SERVICES, 7285 W. Eagle Court, Winton, CA, 95388, US

(73) Assignee: NANJING UNIVERSITY, Nanjing (CN)

(21) Appl. No.: 12/748,435

(22) Filed: Mar. 28, 2010

(30) Foreign Application Priority Data
May 13, 2009 (CN) 200910027926.9

(51) Int. Cl. C30B 25/10; C30B 25/02

(52) U.S. Cl. 117/95; 117/104; 117/94

(57) ABSTRACT

A kind of growth method of non-polarized-plane InN which is growing m-plane InN and In-rich m-plane InGaN on LiA1O₂ (100) substrate by the metal organic chemical vapor deposition (MOCVD), and m-plane is one kind of non-polarized-plane, In-rich denotes that the component of In x is higher than 0.3 in InₓGa₁₋ₓN. The invention synthetically grows m-plane InN and In-rich m-plane InGaN using LiA1O₂ (100) as substrate which will be disposed and the buffer by MOCVD. And the non-polarized-plane InN would be produced through choosing appropriate substrate and the technique condition of growth as well as using the design of buffer by MOCVD.

### CROSS REFERENCE TO RELATED PATENT APPLICATION

This application claims the priority of the Chinese patent application No. 200910027926.9 filed on May 13, 2009, which application is incorporated herein by reference.

### FIELD OF THE INVENTION

This invention involves a new kind of growth method of InN, especially growing InN on LiA1O₂ (100) substrate by the metal organic chemical vapor deposition (MOCVD).

### BACKGROUND OF THE INVENTION

III-Nitrides semiconductor material GaN, A1N and InN are new kinds of semiconductor material with excellent performance. It had important applications in optoelectronic devices, and also has quite wide application prospects in optoelectronic integration, hypervelocity microelectronic devices and ultra-high frequency microwave devices as well as circuit. Due to the difficulty of growth, III-Nitrides cannot be enough attached importance to in quite long time. Until 1991, for the successful preparation of high-brightness GaN LED, the research of III-Nitrides semiconductor growth and devices application had been studied again which had been drowsy many years. By so many years of research and development, the study for growth technology, characteristic and devices application of GaN and A1N has quite great progress. But for InN has low decomposition temperature (decomposition higher than 600° C.) and it should grow at low temperature, however, NH₃ which is as nitrogen source has high decomposition temperature, and the temperature would be about 1000° C. It is a pair of contradiction. Secondly, there is no matching substrate material for growth of InN. This makes it quite difficult for high-quality growth of InN. So the study of InN almost has not any progress. We know little about the properties of InN.

In recent years, for the progress and development of science and technology, the growth technology of InN is riper and riper. Impurities in InN is less and less. Especially the new breakthrough of understanding for the band gap of intrinsic InN in 2002 is that, for purer InN, the band gap is 0.6 ev-0.7 ev rather than 1.9 ev which is believed all along. This make InN has better exhibition in application of microelectronics and optoelectronics. At the same time, there was an international upsurge of studying InN.

Theoretical research indicated that, InN has highest saturated electronic drift velocity and electronic crossover velocity, as well as the least effective electronic mass. Simultaneously its electronic mobility is quite high. So, InN is the ideal high-velocity high-frequency transistor material. Because InN is direct band gap material, and the up to date results indicated that its band gap was 0.6 ev-0.7 ev, that make the band-gap range of In₁₋ₓGaₓN can regulate freely from 0.7 ev of InN to 3.4 ev of GaN along with the component of In x′s change. It provides nearly perfect corresponding matching band gap corresponding to the solar spectra. This provides maximal possibility of designing new efficient solar battery. In theory, photoelectric conversion efficiency of solar battery based on InN has possibility to approach 72% which is the ultimate photoelectric conversion efficiency of solar battery in theory. For the reduction of intrinsic band gap, emission wavelength of InN achieved 1.55 μm, thus people can cover from ultraviolet to infrared waveband through continuously adjustive change of growing components by III-Nitrides, and it can be extended to long wavelength communication band, so the optional material of preparation for optical communication devices can be more abundant. At the same time, InN can possibly bring new breakthrough for development of optical communication devices by its unique excellent properties.

At present, a majority of material based on GaN is wurtzite structure growing along with [0001] c axis. However, epitaxial growing along with [0001] would produce spontaneous polarization and piezoelectric polarization, inducing quantum-confined stark effect, and the built-in electric field because of it weakens overlapped possibility of electron and hole wave function in quantum well in the real space, reducing the quantum efficiency of devices; also make the transition emitting energy of optoelectronic devices having red shift. By way of conquering these disadvantages, (1100)m-plane and (1102) a-pine GaN causes people's a world of interest. M-plane and a-plane GaN can grow on c-plane LiA10_{2 or} r-plane sapphire substrate by MOCVD, MBE, HVPE.

Substrate quite influences the crystal quality of heter-epitaxy GaN, and engenders important influence to capability and reliability of devices. It is one of the main difficulties which influences the maturity of GaN devices that there is no appropriate substrate which matches GaN lattice and has heat compatibility. At present, the lattice mismatch of the most widely used c-plane sapphire (c-plane-Al₂O₃) substrate with GaN is as high as 13.6%. Though the match of epitaxial film with substrate can be improved by buffer, but the bad lattice mismatching would induce the production of high density defects, making the life and capability of devices greatly decline. Although foreground of homoepitaxy on GaN substrate is attractive, but growing large size GaN single crystals needs some time, and finding other ideal substrate is one of the effective approach for solving problem. LiA1O_{2 matches} with GaN quite well and the lattice mismatch of it with GaN is only 1.4%, so it is substrate having developing foreground for GaN growing. The work of synthetic growing m-plane GaN by MBE, HVPE et al. technologies on c-plane LiA1O₂ substrate has been reported by many literatures, but there is nearly no reports about growing non-polarized-plane InN.

### SUMMARY OF THE INVENTION

The aim of this invention is: providing a kind of growth method for growing m-plane InN films and In-rich m-plane InGaN on LiA1O₂ (100) substrate by metal organic chemical vapor deposition MOCVD peter-epitaxy growth system. The technology project of this invention is: a kind of growth method of non-polarized-plane InN, which characteristic is growing m-plane InN and In-rich m-plane InGaN on LiA1O₂ (100) substrate by the metal organic chemical vapor deposition (MOCVD), and m-plane is one kind of non-polarized-plane, In-rich denotes that the component of In x is higher than 0.3 in InₓGa₁₋ₓN.

In the system of MOCVD, firstly, the growing LiAlO₂ (100) substrate would be heat treated at 500-1050° C. or pumping in ammonia for the surface nitridation; then pump in carrier gas N₂, ammonia and metalorganic sources, and grow m-plane InN and In-rich m-plane InGaN on LiA1O₂ (100) substrate.

Heat treatment for growing LiA1O₂ (100) substrate is: heat treatment of 10 seconds to 300 seconds for substrate at 500-800° C. by hydrogen or nitrogen.

The LiA1O₂ (100) substrate that has been heat treated or surface nitrided, is pumped in carrier gas nitrogen, ammonia and metalorganic sources of In and Ga at 450-600° C., and grow low temperature GaN buffer and low temperature InN buffer; then grow In-rich m-plane InN on buffer or the treated substrate, and the condition for growth of m-plane InGaN is at 500-700° C., the growth pressure is 0-700 Torr, and the mole ratio of pentiels and triels for growth is 500-30000, the growth time is controlled according to the thickness of material. The thickness of low temperature GaN buffer and the low temperature InN buffer is 5-100 nm.

The low temperature buffer in this invention can has the effect of nucleation which is propitious to nucleation-grow to monocrystal. When growing InGaN, the component of in is defined by the input quantity of sources of Ga and in which control mol ratio of pentiels with triels being 500-30000,and the specific flux is fixed.

The invention uses LiA1O₂ (100) material as substrate, and the key of the invention is the disposal of the LiA1O₂ (100) substrate and growing low temperature GaN and InN buffer for nucleation-growing to monocrystal.

The invention synthetically grows m-plane InN and In-rich m-plane InGaN using LiA1O₂ (100) as substrate which will be disposed and the buffer by MOCVD. And the non-polarized-plane InN would be produced through choosing appropriate substrate and the technique condition of growth as well as using the design of buffer by MOCVD.

### BRIEF DESCRIPTION OF THE DRAWINGS

FIG. 1 High resolution X-ray diffraction ω-2θ scanning spectrum of m-plane InN in the invention.

FIG. 2 Rocking curve at azimuth 0° and 90° of m-plane InN in the invention.

FIG. 3 Atomic force microscopic picture of m-plane InN in the invention, (a) and (b) are different samples.

FIG. 4 The room temperature PL spectra and the optical absorption of 2 μm-thick m-plane InN film grown at T=600° C.

### DETAIL DESCRIPTION OF THE INVENTION

The invention is growing m-plane InN and In-rich m-plane InGaN on LiA1O₂ (100) substrate by the metal organic chemical vapor deposition (MOCVD), and m-plane is one kind of non-polarized-plane, In-rich denotes that the component of in x is higher than 0.3 in InₓGa₁₋ₓN. It concretely includes the following step:

Using LiA1O₂ (100) as substrate, firstly, the substrate would be heat treated at 500-800° C. for 10s to 300s by hydrogen or nitrogen, or surface nitrided by pumping in ammonia, then pump in carrier gas N₂, ammonia and metalorganic sources at 500-1050° C.

After the above surface treatment to LiAlO₂ (100) substrate, the ammonia and metalorganic sources, for example, trimethyl indium, are pumped in by the nitrogen or hydrogen as the carrier gas, and the low temperature InN buffer would grow at 450-600° C. for 10s-300s. When growing, the growth pressure is 0-700 Torr, and the mol ratio of pentiels and triels is controlled from 500 to 30000 by carrier gas flow. When growing m-plane InGaN, only metalorganic source In is pumped in, and if growing In-rich m-plane InGaN, the metalorganic sources include In and Ga, for example, trimethyl indium and trimethyl gallium, producing low temperature InN and GaN buffer. The above thickness of low temperature GaN and InN buffer are 5-100 nm.

After above techniques, the ammonia and metalorganic sources are continued to pumped in by nitrogen or hydrogen as carrier gas, then raising the temperature to 500-650° C., and beginning to grow m-plane InN or In-rich m-plane InGaN. The growth time is controlled according to the thickness of growth material. Similarly, the growth pressure is 0-700 Torr, and the mol ratio of pentiels and triels is controlled from 500 to 30000 by carrier gas flow.

FIG. 1 is high resolution X-ray diffraction ω-2θ scanning spectrum of m-plane InN in the invention. It can be seen from the figure there are no other peaks except characteristic peaks of LAO(200), LAO (400) of substrate, (100) of m-plane InN and (400) of m-plane InN, indicating that the growing InN are all m-plane. LAO denotes lithium aluminate.

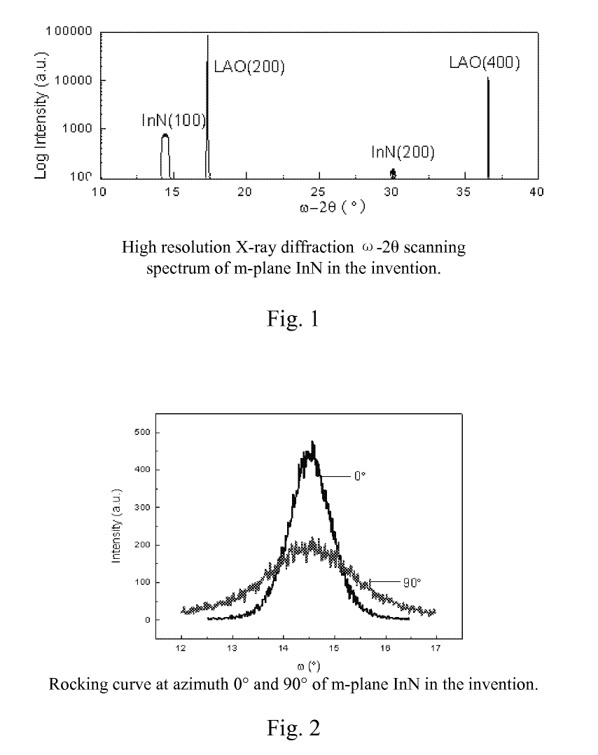

FIG. 2 is X-ray rocking curve of the growth InN in the invention. It can be seen that sample has different peak half-width, accounting for that m-plane InN has plane anisotropy.

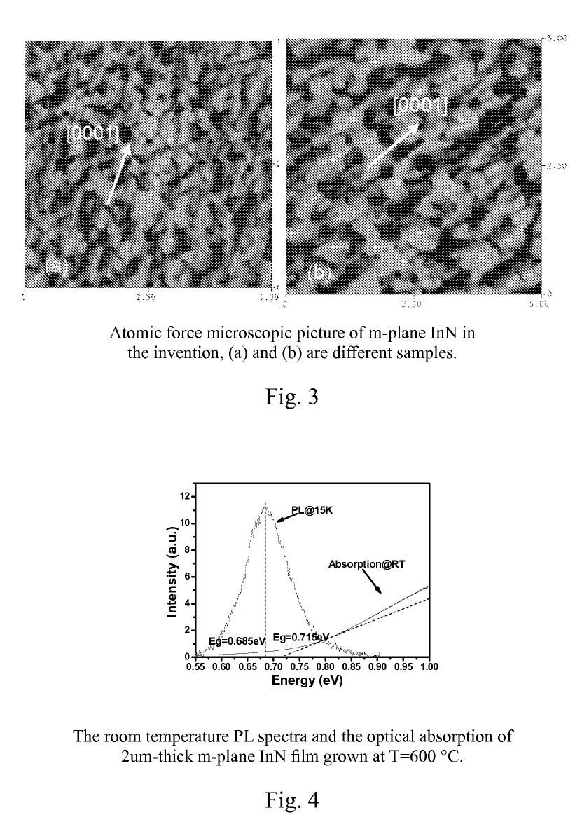

FIG. 3 is atomic force microscopic picture of m-plane InN in the invention, (a) and (b) are different samples. It can be seen from the figure, the surface of the growing m-plane InN is comparative even, and the roughness of surface (RMS) is 27 nm. InN crystal grows with quasi-two-dimension mode, and the grain size of surface is small, and present structure anisotropy at all direction in [0001] plane. This agrees with FIG. 2 as well as the result of the research for cathode-luminescence.

FIG. 4 is the room temperature PL spectra and the optical absorption of 2 μm-thick m-plane InN film grown at T=600° C. indicated a band gap energy of 0.72 eV and PL peak energy of 0.69 eV. Take no account of the Burstein-Moss effect, we can show that the band gap of the two structure m-plane InN film FIG. 5 indicated a band gap energy of 0.715 eV and PL peak energy of 0.685 eV at the room temperature. The redshift of the PL peak with regard to the band gap implies that the emission may be related largely to bandtail states. All films grown within the investigated thickness range of 1-2 μm resulted in consistently low band gap energies between 0.72-0.75 eV and PL peak energies between 0.65-0.70 eV.

The invention synthetically grows m-plane InN on LiA1O₂ (100) substrate by MOCVD. It has been reported by many literature that the study of synthetically growing m-plane GaN using c-plane LiA1O₂ (LAO) as substrate by technology such as MBE and HVPE. However, there is no similar technical scheme that synthetically growing m-plane InN by MOCVD. The invention for the first time synthetically grows m-plane InN films on LiA1O₂ (100) substrate by MOCVD, and it is the first time in technique.

Growth method of the metal organic chemical vapor deposition (MOCVD) is a kind of usual material growth method, but how to choose substrate and how to get highly crystalline high-quality InN is all the same worth to study. The problems to be solved in producing include the technique condition of growth, the design of buffer et al. The invention is a contrivance in material, an improvement in growth method, and has more development in purpose.

What is claimed is:

1. A growth method of non-polarized-plane InN, comprising growing m-plane InN and In-rich m-plane InGaN on LiA1O₂ (100) substrate by metal organic chemical vapor deposition (MOCVD), and the m-plane is one kind of non-polarized-plane, the In-rich denotes that a component of In x is higher than 0.3 in InₓGa₁₋ₓN.

2. The growth method of non-polarized-plane InN according to claim 1, wherein in the system of MOCVD, firstly, the growing LiA1O₂ (100) substrate is heat treated at 500-1050° C. or pumping in ammonia for the surface nitridation; then pump in carrier gas N₂, ammonia and metalorganic sources, and grow the m-plane InN and the In-rich m-plane InGaN on the LiA1O₂ (100) substrate.

3. The growth method of non-polarized-plane InN according to claim 2, wherein the heat treatment for growing LiA1O₂ (100) substrate: heat treatment of 10 seconds to 300 seconds for the substrate at 500-800° C. by hydrogen or nitrogen.

4. The growth method of non-polarized-plane InN according to claim 2, wherein firstly, the LiA1O₂ (100) substrate that has been heat treated or surface nitrided is pumped in carrier gas nitrogen, ammonia and metalorganic sources of In at 450-600° C., and grow a layer of low temperature InN buffer; then grow m-plane InN on buffer or the treated substrate, and a condition for growth is at 500-700° C., a growth pressure is 0-700 Torr, and a mole ratio of pentels and triels for growth is 500-30000, a growth time is controlled according to the thickness of material.

5. The growth method of non-polarized-plane InN according to claim 3, wherein firstly, the LiA1O₂ (100) substrate that has been heat treated or surface nitrided is pumped in carrier gas nitrogen, ammonia and metalorganic sources of In at 450-600° C., and grow a layer of low temperature InN buffer; then grow m-plane InN on buffer or the treated substrate, and a condition for growth is at 500-700° C., a growth pressure is 0-700 Torr, and a mole ratio of pentels and triels for growth is 500-30000, a growth time is controlled according to the thickness of material.

6. The growth method of non-polarized-plane InN according to claim 4, wherein a thickness of the low temperature InN buffer is 5-100 nm.

7. The growth method of non-polarized-plane InN according to claim 5, wherein a thickness of the low temperature InN buffer is 5-100 nm.

8. The growth method of non-polarized-plane InN according to claim 2, wherein firstly, the LiA1O₂ (100) substrate that has been heat treated or surface nitriding, is pumped in carrier gas nitrogen, ammonia and metalorganic sources of In and Ga at 450-600° C., and grow a low temperature GaN buffer and a low temperature InN buffer; then grow the In-rich m-plane InN on the buffer or the treated substrate, and a condition for growth of m-plane InGaN is at 500-700° C., a growth pressure is 0-700 Torr, and a mole ratio of pentiels and triels for growth is 500-30000, a growth time is controlled according to thickness of material.

9. The growth method of non-polarized-plane InN according to claim 3, wherein firstly, the LiA1O₂ (100) substrate that has been heat treated or surface nitriding, is pumped in carrier gas nitrogen, ammonia and metalorganic sources of In and Ga at 450-600° C., and grow a low temperature GaN buffer and a low temperature InN buffer; then grow the In-rich m-plane InN on the buffer or the treated substrate, and a condition for growth of m-plane InGaN is at 500-700° C., a growth pressure is 0-700 Torr, and a mole ratio of pentiels and triels for growth is 500-30000, a growth time is controlled according to thickness of material.

10. The growth method of non-polarized-plane InN according to claim 8, wherein a thickness of the low temperature GaN buffer and the low temperature InN buffer is 5-100 nm.

11. The growth method of non-polarized-plane InN according to claim 9, wherein a thickness of the low temperature GaN buffer and the low temperature InN buffer is 5-100 nm.
